(19) United States
(12) Patent Application Publication
(10) Pub. No.: US 2020/0300930 A1
(43) Pub. Date: Sep. 24, 2020

(54) METHOD FOR PRODUCING MI ELEMENT AND MI ELEMENT

(71) Applicant: NIDEC READ CORPORATION, Kyoto (JP)

(72) Inventors: Masami YAMAMOTO, Kyoto (JP); Kazuhiko KITANO, Kyoto (JP); Norihiro OTA, Kyoto (JP); Shigeki SAKAI, Kyoto (JP); Kiyoshi NUMATA, Kyoto (JP)

(21) Appl. No.: 16/770,631

(22) PCT Filed: Nov. 26, 2018
(86) PCT No.: PCT/JP2018/043405

§ 371 Date: Jun. 8, 2020

(30) Foreign Application Priority Data
Dec. 8, 2017 (JP) 2017-236346

(51) Int. Cl. G01R 33/02; H01L 43/12; H01F 41/04

(52) U.S. Cl. CPC G01R 33/02; H01F 41/04; H01L 43/12

(57) ABSTRACT

A method for producing an MI element includes: an insulation step of forming an insulator layer on an outer periphery of an amorphous wire; an electroless plating step of forming an electroless plating layer on an outer peripheral surface of the insulator layer; an electrolytic plating step of forming an electrolytic plating layer on an outer peripheral surface of the electroless plating layer; a resist step of forming a resist layer on an outer peripheral surface of the electrolytic plating layer; an exposure step of exposing the resist layer with a laser to form a spiral groove strip on an outer peripheral surface of the resist layer; an etching step of performing etching using the resist layer as a masking material and removing the electroless plating layer and the electrolytic plating layer in the groove strip to form a coil with the remaining electroless plating layer and electrolytic plating layer.

### CROSS-REFERENCE TO RELATED APPLICATIONS

This application is a U.S. national stage entry according to 35 U.S.C. § 371 of PCT application No. PCT/JP2018/043405, filed on Nov. 26, 2018, with priority under 35 U.S.C. § 119(a) and 35 U.S.C. § 365(b) being claimed from Japanese Application No. 2017-236346, filed on Dec. 8, 2017; the disclosures of which are incorporated herein by reference in their entirety.

### FIELD OF THE INVENTION

The present disclosure relates to a method for producing an MI element and an MI element, and more particularly to a technique for simplifying an equipment configuration at the time of producing the MI element.

### BACKGROUND

Conventionally, there is known a magneto-impedance (MI) element including a magnetic sensitive member made of an amorphous wire and an electromagnetic coil wound around the magnetic sensitive member with an insulator interposed therebetween. There is known a technique in which a metal material containing copper is vacuum-deposited on an outer peripheral surface of an insulator to form a metallic film, and then, an electromagnetic coil is formed by selective etching.

When the vacuum deposition is used to form the metallic film as in the above-described conventional technique, it is difficult to increase a thickness of the metallic film. When the thickness of the metallic film is small in the MI element, it is difficult to sufficiently ensure a current path cross-sectional area of a current flowing through the electromagnetic coil, and there is a possibility that the performance of the MI element is insufficient.

In order to solve the above problem, the present disclosure provides a method for producing an MI element and an MI element configured as follows.

### SUMMARY

A method for producing an MI element according to an exemplary embodiment of the present disclosure includes: an insulation step of forming an insulator layer on an outer periphery of an amorphous wire; an electroless plating step of forming an electroless plating layer on an outer peripheral surface of the insulator layer; an electrolytic plating step of forming an electrolytic plating layer on an outer peripheral surface of the electroless plating layer; a resist step of forming a resist layer on an outer peripheral surface of the electrolytic plating layer; an exposure step of exposing the resist layer with a laser to form a spiral groove strip on an outer peripheral surface of the resist layer; and an etching step of performing etching using the resist layer as a masking material and removing the electroless plating layer and the electrolytic plating layer in the groove strip to form a coil with the remaining electroless plating layer and electrolytic plating layer.

Further, an MI element according to an exemplary embodiment of the present disclosure includes: an amorphous wire; an insulator layer formed on an outer periphery of the amorphous wire; and a coil formed in a spiral shape on an outer peripheral surface of the insulator layer, the coil being formed of two layers of an electroless plating layer and an electrolytic plating layer formed on an outer peripheral surface of the electroless plating layer.

The above and other elements, features, steps, characteristics and advantages of the present disclosure will become more apparent from the following detailed description of the preferred embodiments with reference to the attached drawings.

### BRIEF DESCRIPTION OF THE DRAWINGS

In the drawings, like reference characters generally refer to the same parts throughout the different views. The drawings are not necessarily to scale; emphasis instead generally being placed upon illustrating the principles of the disclosed embodiments. In the following description, various embodiments described with reference to the following drawings, in which

FIG. 1 is a plan view illustrating an MI element according to a first embodiment;

FIG. 2 is a cross-sectional view taken along line II-II in FIG. 1;

FIG. 3 is a cross-sectional view taken along line III-III in FIG. 1;

FIG. 4 is a view illustrating each producing process of the MI element according to the first embodiment;

FIG. 5 is an enlarged cross-sectional view illustrating a surface portion of the MI element according to the first embodiment;

FIG. 6 is a plan view illustrating an MI element according to a second embodiment;

FIG. 7 is a cross-sectional view taken along line VII-VII in FIG. 6; and

FIG. 8 is a view illustrating each producing process of the MI element according to the second embodiment.

### DETAILED DESCRIPTION

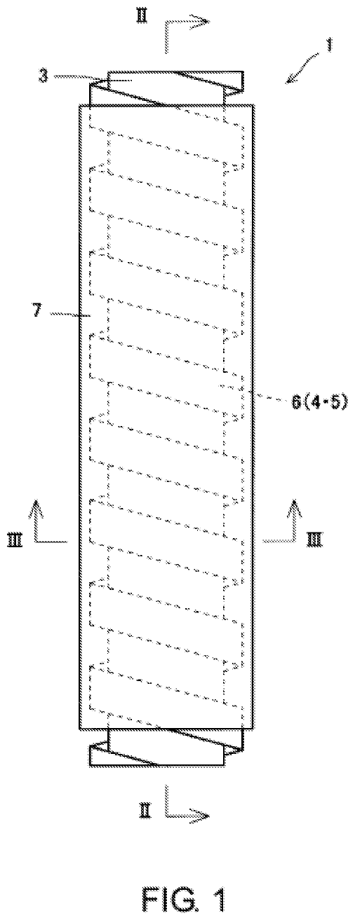

First, a configuration of a magneto-impedance element (hereinafter simply referred to as “MI element”) 1 according to a first embodiment of the present disclosure will be described with reference to FIGS. 1 to 3. The MI element 1 performs magnetic sensing by utilizing a so-called MI phenomenon in which an induced voltage is generated in a coil 6 in response to a change in a current flowing through a magnetic sensitive member (an amorphous wire 2 in the present embodiment).

The above-described MI phenomenon occurs with respect to the magnetic sensitive member made of a magnetic material having an electron spin arrangement in a circumferential direction with respect to a direction of the supplied current. When the current energizing this magnetic sensitive member is rapidly changed, a magnetic field in the circumferential direction is rapidly changed, and a spin direction of an electron changes in response to a peripheral magnetic field due to the action of the above change in the magnetic field. Then, the MI phenomenon is a phenomenon in which changes of internal magnetization of the magnetic sensitive member, an impedance, and the like occur at that time.

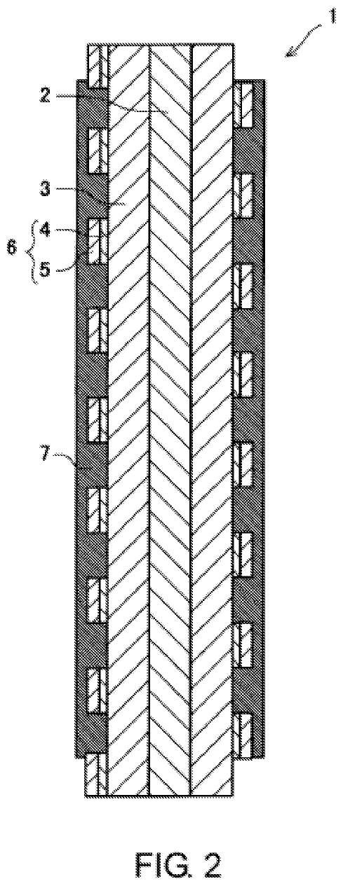

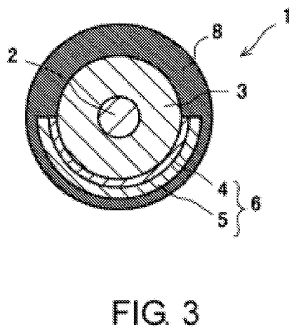

As illustrated in FIGS. 2 and 3, the amorphous wire 2 which is a filament having a circular outer peripheral shape, such as CoFeSiB having a diameter of several tens of μm or less, is used as the magnetic sensitive member in the MI element 1 according to the present embodiment. An insulator layer 3 made of acrylic resin is formed on an outer periphery of the amorphous wire 2 such that an outer peripheral shape of a cross section is circular. Specifically, the outer peripheral shape of the insulator layer 3 is formed in a circular shape concentric with the outer peripheral shape of the amorphous wire 2, that is, such that a thickness of the insulator layer 3 is uniform in the circumferential direction. Specifically, the amorphous wire 2 is immersed in an electrodeposition coating material in which an acrylic resin material is dispersed in a liquid in an ionic state, and a voltage is applied between the amorphous wire 2 and the electrodeposition coating material in a bath, so that the acrylic resin in the ionic state is electrodeposited on the amorphous wire. According to such a method, the thickness of the insulator layer can be controlled by the voltage to be applied. The electrodeposition coating material thus formed on the surface of the amorphous wire 2 is baked and solidified at a high temperature of, for example, 100 degrees or more to form the insulator layer 3.

The coil 6 is spirally formed on an outer peripheral surface of the insulator layer 3. The coil 6 is formed of two layers of an electroless plating layer 4 and an electrolytic plating layer 5 formed on an outer peripheral surface of the electroless plating layer 4. As illustrated in FIG. 2, the coil 6 is covered with a layer of resin 7 except for both ends which are coil terminals, and a gap between the coils 6 is filled with the resin 7. As a result, the resin 7 enters the gap between the coils 6 and makes it difficult for the coil 6 to be separated from the insulator layer 3.

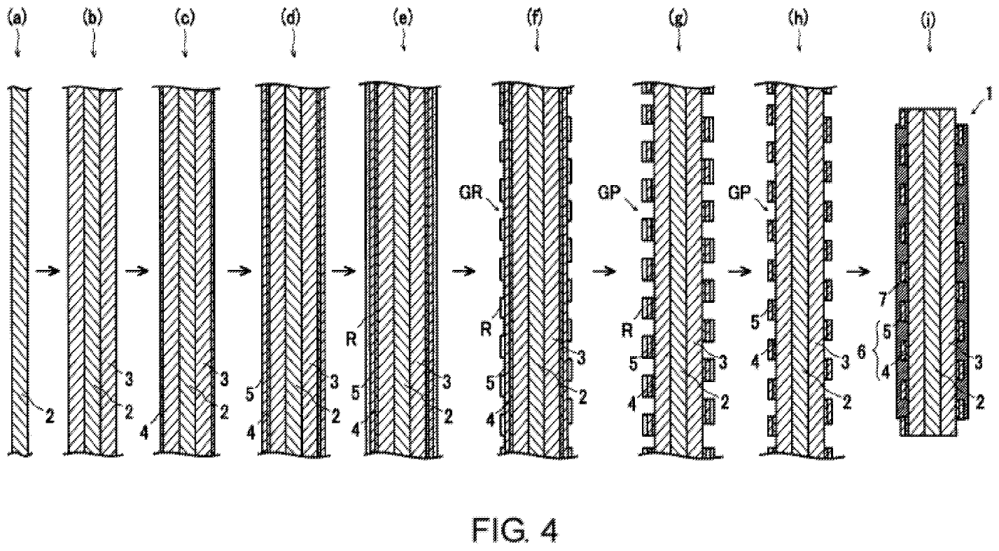

Next, a method for producing the MI element 1 will be described with reference to FIG. 4. In FIG. 4, (a) illustrates the amorphous wire 2 before an insulation step, (b) illustrates a state after the insulation step, (c) illustrates a state after an electroless plating step, (d) illustrates a state after an electrolytic plating step, (e) illustrates a state after a resist step, (f) illustrates a state after an exposure step, (g) illustrates a state after an etching step, (h) illustrates a state after a resist removal step, and (i) illustrates a state after a coating step.

When producing the MI element 1 according to the present embodiment, the amorphous wire 2 which is the filament having the circular outer peripheral shape is prepared as illustrated in (a) of FIG. 4. Then, an insulator is applied to an outer periphery of the amorphous wire 2 to form the insulator layer 3 as illustrated in (b) of FIG. 4 (the insulation step). At this time, the insulator layer 3 is formed such that the outer peripheral shape in the cross section is the circular shape concentric with the outer peripheral shape of the amorphous wire 2, that is, such that the thickness of the insulator layer 3 is uniform in the circumferential direction as illustrated in FIG. 3.

Next, electroless Cu plating is performed to form the electroless plating layer 4 on an outer peripheral surface of the insulator layer 3 as illustrated in (c) of FIG. 4 (the electroless plating step). Note that electroless Au plating can be also used in this step. Next, electrolytic Cu plating is performed to form the electrolytic plating layer 5 on an outer peripheral surface of the electroless plating layer 4 as illustrated in (d) of FIG. 4 (the electrolytic plating step). Note that electrolytic Au plating can be also used in this step. In this manner, a metallic film is formed on the insulator layer 3 using the electroless plating and the electrolytic plating in the present embodiment.

Next, the amorphous wire 2 on which the electrolytic plating layer 5 has been formed is immersed in a photoresist bath containing a photoresist solution, and then, is pulled up at a predetermined speed (for example, speed of 1 mm/sec), thereby forming a resist layer R on an outer peripheral surface of the electrolytic plating layer 5 as illustrated in (e) of FIG. 4 (the resist step).

Next, the resist layer R is exposed with a laser and the laser-exposed portion is dissolved with a developer to form a spiral groove strip GR on an outer peripheral surface of the resist layer R and to expose the electrolytic plating layer 5 of the groove strip GR as illustrated in (f) of FIG. 4 (the exposure step).

The laser exposure in the above-described exposure step is performed while performing rotation around a central axis of the amorphous wire 2 on which the resist layer R is formed, and causing displacement in the axial direction. In the present embodiment, a positive photoresist is adopted in which the laser-exposed portion is dissolved in the developer to form the spiral groove strip GR in the resist layer R. Note that, it is also possible to use a negative photoresist in which a portion not exposed to laser is dissolved in a developer to form a spiral groove strip in the resist layer in this step.

Next, etching is performed using the resist layer remaining on the outer periphery of the electrolytic plating layer 5 as a masking material by immersing the amorphous wire 2 having the groove strip GR formed in the resist layer R in an acidic electrolytic polishing solution to perform electrolytically polishing. As a result, the electroless plating layer 4 and the electrolytic plating layer 5 in portions where the groove strips GR are used to be formed in the resist layer R are removed as illustrated in (g) of FIG. 4 (the etching step).

As illustrated in (g) of FIG. 4, a spiral groove GP is formed in portions where the groove strips GR are used to be formed in the electroless plating layer 4 and the electrolytic plating layer 5. That is, the remaining electroless plating layer 4 and electrolytic plating layer 5 are formed as the coil 6 in this step.

Next, the resist layer R is removed using a stripping solution or the like as illustrated in (h) of FIG. 4 (the resist removal step). Then, the amorphous wire 2, the insulator layer 3, and the coil 6 are cut into a predetermined length, and then, the coil 6 is covered with the layer of the resin 7 except for both ends, and a gap between the coils 6 is filled with the resin 7 as illustrated in (i) of FIG. 4 (the coating step).

As described above, in the method for producing the MI element 1 according to the present embodiment, the electroless plating and the electrolytic plating are used without using vacuum deposition at the time of forming the metallic film on the outer peripheral surface of the insulator layer 3. With the plating, it is easy to form the metallic film to have a large thickness, and thus, it is possible to ensure a sufficient current path cross-sectional area of a current flowing through an electromagnetic coil. That is, according to the method for producing the MI element of the present embodiment, the performance of the MI element can be ensured by ensuring the current path cross-sectional area of the electromagnetic coil.

In the case of using vacuum deposition at the time of forming a metallic film, it is necessary to set a chamber containing a target object (one with an insulator provided around a magnetic sensitive member) in a vacuum state, and thus, an equipment configuration is a large scale so that production cost is high. However, in the case of using the electroless plating and the electrolytic plating to form the metallic film as in the present embodiment, the vacuum chamber is unnecessary, and the equipment configuration can be simplified so that the production cost of the MI element 1 can be suppressed.

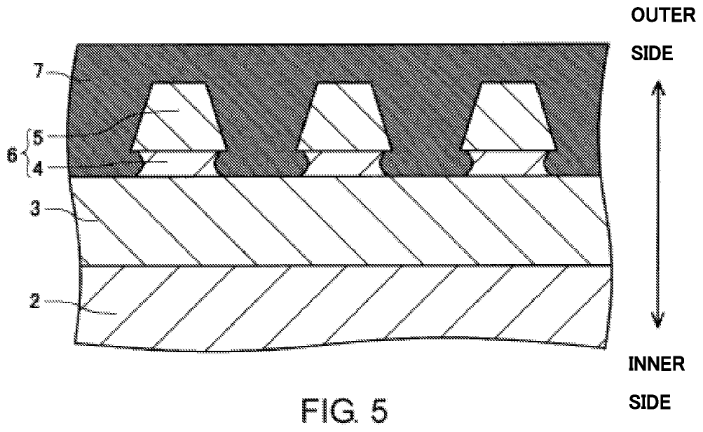

Further, in the MI element 1 according to the present embodiment, the coil 6 is covered with the layer of the resin 7, and the gap between the coils 6 is filled with the resin 7. As a result, the resin 7 enters the gap between the coils 6 and makes it difficult for the coil 6 to be separated from the insulator layer 3. Specifically, the etching is performed sequentially from the outer side to the inner side in the etching step, and thus, an etching solution has a longer contact time with an outer portion of the electrolytic plating layer 5 (the outer portion in the radial direction of the coil 6). For this reason, the outer portion of the electrolytic plating layer 5 is etched more than the inner portion to be thinner as illustrated in FIG. 5. On the other hand, since the electroless plating layer 4 has a lower density than the electrolytic plating layer 5, the electroless plating layer 4 is etched a lot to be recessed inward as illustrated in FIG. 5. As a result, when the coil 6 is coated with the resin 7 in the coating step, the resin 7 is changed so as to wrap around toward the electroless plating layer 4, and this portion has a shape to be caught. As a result, a stronger anchor effect can be obtained.

Further, in the method for producing the MI element 1 according to the present embodiment, the outer peripheral shape of the cross section of the insulator layer 3 is formed into the circular shape in the insulation step so that the thickness of the insulator layer 3 is formed uniformly in the circumferential direction. As a result, a distance between the amorphous wire 2 and the coil 6 formed on the outer peripheral surface of the insulator layer 3 can be made constant, and thus, it is possible to improve the sensitivity of the MI element 1.

More specifically, in the technique disclosed in Patent Literature 1, an amorphous wire has a circular cross section, whereas an insulator layer has a rectangular cross section. For this reason, a distance between a wire and a coil becomes large depending on a position in the circumferential direction, and as a result, the sensitivity of a sensor becomes low.

In the MI element 1 according to the present embodiment, however, the thickness of the insulator layer 3 is formed uniformly in the circumferential direction by forming the circular insulator layer 3 on the surface of the amorphous wire 2 having the circular cross section. For this reason, the distance between the amorphous wire 2 and the coil 6 can be made constant regardless of the position in the circumferential direction, and as a result, the sensitivity of the MI sensor 1 can be increased.

Note that it is unnecessary to limit the outer peripheral shapes of the amorphous wire 2 and the insulator layer 3 to the circular shape in order to make the distance between the amorphous wire 2 and the coil 6 constant regardless of the position in the circumferential direction. For example, it is also possible to form an insulator layer having a rectangular shape (specifically, a rectangular shape whose a corners are chamfered in a circular shape) on a surface of an amorphous wire having a rectangular cross section so as to have the uniform thickness in the circumferential direction. Even in this case, a distance between the amorphous wire and the coil can be constant regardless of the position in the circumferential direction, and as a result, the sensitivity of the MI sensor 1 can be increased.

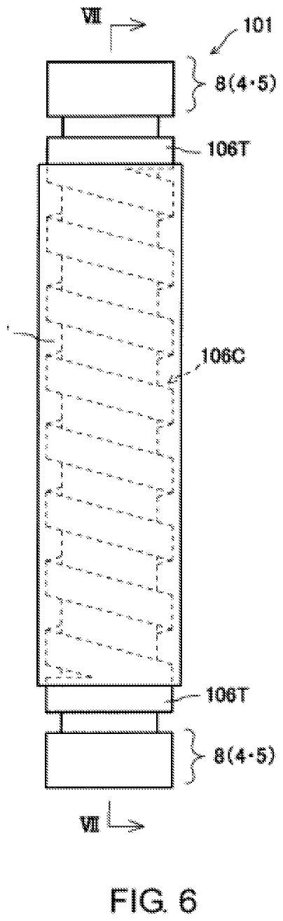

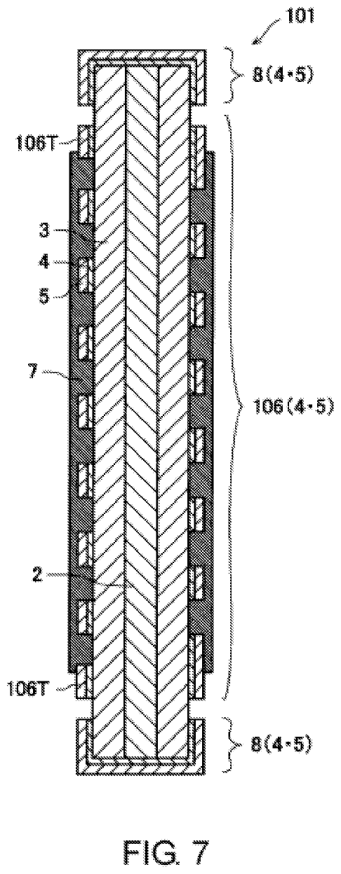

Next, a configuration of an MI element 101 according to a second embodiment of the present disclosure will be described with reference to FIGS. 6 and 7. In the present embodiment, a detailed description of the configurations common to those of the MI element 1 according to the first embodiment will be omitted, different configurations will be mainly described.

As illustrated in FIG. 7, the insulator layer 3 is formed on an outer periphery of the amorphous wire 2 even in the MI element 101 according to the present embodiment, similarly to the MI element 1 according to the first embodiment. Then, a coil 106 is spirally formed on an outer peripheral surface of the insulator layer 3. The coil 106 is formed of two layers of the electroless plating layer 4 and the electrolytic plating layer 5 formed on an outer peripheral surface of the electroless plating layer 4. In the MI element 101 according to the present embodiment, both ends of the coil 106 are formed as annular coil electrodes 106T and 106T each surrounding the insulator layer 3 in the circumferential direction, and a spiral portion between the coil electrodes 106T and 106T is formed as a coil portion 106C. As illustrated in FIG. 7, the coil portion 106C of the coil 106 is covered with a layer of the resin 7, and a gap between the coil portions 106C is filled with the resin 7.

Further, both ends of the amorphous wire 2 are connected to electrodes 8 and 8 each formed of the electroless plating layer 4 that covers an end of the insulator layer 3 and the electrolytic plating layer 5 formed on an outer peripheral surface of electroless plating layer 4.

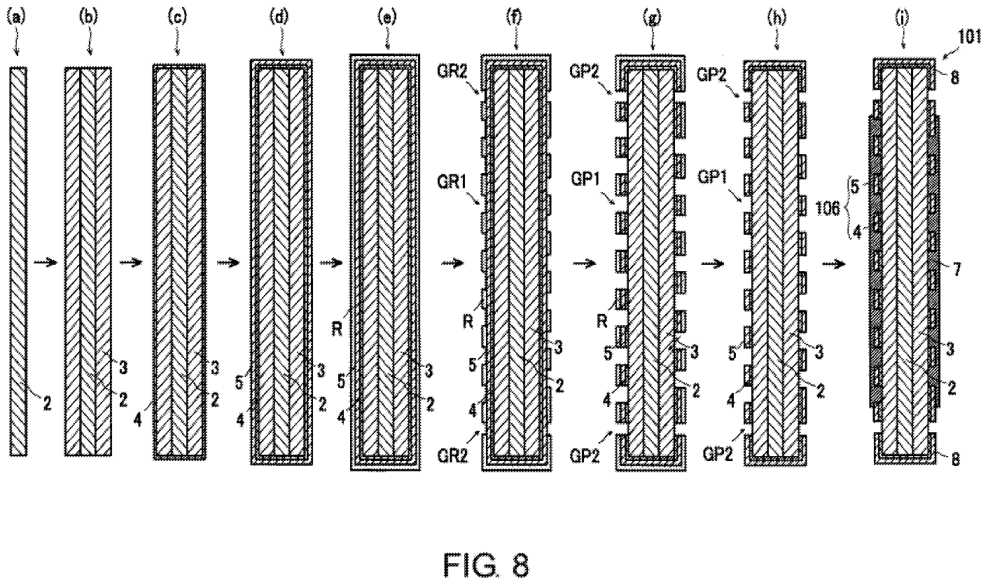

Next, a method for producing the MI element 101 will be described with reference to FIG. 8. In FIG. 8, (a) illustrates the amorphous wire 2 before an insulation step, (b) illustrates a state after the insulation step, (c) illustrates a state after an electroless plating step, (d) illustrates a state after an electrolytic plating step, (e) illustrates a state after a resist step, (f) illustrates a state after an exposure step, (g) illustrates a state after an etching step, (h) illustrates a state after a resist removal step, and (i) illustrates a state after a coating step.

When producing the MI element 101 according to the present embodiment, the amorphous wire 2 cut into a predetermined length (several mm) is prepared as illustrated in (a) of FIG. 8. Then, an insulator such as a silicon rubber is applied in a cylindrical shape on an outer periphery of the amorphous wire 2 to form the insulator layer 3 as illustrated in (b) of FIG. 8 (the insulation step). At this time, both ends of the amorphous wire 2 are exposed at both ends of the insulator layer 3.

Next, electroless Cu plating (or electroless Au plating) is performed to form the electroless plating layer 4 on an outer peripheral surface of the insulator layer 3 as illustrated in (c) of FIG. 8 (the electroless plating step). At this time, the electroless plating layer 4 is formed so as to come into contact with the both ends of the amorphous wire 2. Next, electrolytic Cu plating (or electrolytic Au plating) is performed to form the electrolytic plating layer 5 on an outer peripheral surface of the electroless plating layer 4 as illustrated in (d) of FIG. 8 (the electrolytic plating step).

Next, the amorphous wire 2 on which the electrolytic plating layer 5 has been formed is immersed in a photoresist bath containing a photoresist solution, and then, is pulled up at a predetermined speed (for example, speed of 1 mm/sec), thereby forming a resist layer R on an outer peripheral surface of the electrolytic plating layer 5 as illustrated in (e) of FIG. 8 (the resist step).

Next, the resist layer R is exposed with a laser and the laser-exposed portion is dissolved with a developer to form a spiral groove strip GR1 and an annular groove GR2, which surrounds the resist layer R to be separated from both ends of the groove strip GR1 on the outer end side on an outer peripheral surface of the resist layer R and to expose the electrolytic plating layer 5 of the groove strip GR1 and the annular groove GR2 as illustrated in (f) of FIG. 8 (the exposure step). The laser exposure in the above-described exposure step is performed over a plurality of times while performing rotation around a central axis of the amorphous wire 2 on which the resist layer R is formed, and causing displacement in the axial direction.

Next, in the etching step, etching is performed using the resist layer remaining on the outer periphery of the electrolytic plating layer 5 as a masking material by immersing the amorphous wire 2 having the groove strip GR1 and the annular groove GR2 formed in the resist layer R in an acidic electrolytic polishing solution to perform electrolytically polishing. As a result, the electroless plating layer 4 and the electrolytic plating layer 5 in portions where the groove strip GR1 and the annular groove GR2 are used to be formed in the resist layer R are removed as illustrated in (g) of FIG. 8 (the etching step).

As illustrated in (g) of FIG. 8, a spiral groove GP1 is formed in portions where the groove strips GR1 are used to be formed in the electroless plating layer 4 and the electrolytic plating layer 5. Further, the annular groove GP2 is formed in the portion where the annular groove GR2 is used to be formed. The annular groove GP2 divides the electroless plating layer 4 and the electrolytic plating layer 5 into a central portion forming the coil 106 and both end portions forming the electrodes 8 and 8. That is, in this step, the electroless plating layer 4 and the electrolytic plating layer 5 remaining on the outer end side of the annular groove GP2 are formed as the electrodes 8 and 8 of the amorphous wire 2, and the electroless plating layer 4 and the electrolytic plating layer 5 remaining between the annular grooves GP2 are formed as the coil 106.

Since the groove strip GR1 and the annular groove GR2 are formed to be separated in the present embodiment, the groove GP1 is formed to be separated from the annular groove GP2. As a result, both ends of the coil 106 are formed as the annular coil electrodes 106T and 106T each surrounding the insulator layer 3, and the spiral portion between the coil electrodes 106T and 106T is formed as the coil portion 106C.

Next, the resist layer R is removed using a stripping solution or the like as illustrated in (h) of FIG. 8 (the resist removal step). Then, the coil 106 is covered with the layer of the resin 7, and the gap between the coils 106 is filled with the resin 7 as illustrated in (i) of FIG. 8 (the coating step).

According to the method for producing the MI element 101 of the present embodiment, the electrodes 8 and 8 of the amorphous wire 2 are formed by the electroless plating layer 4 and the electrolytic plating layer 5 remaining on the outer end side of the annular groove GPL (the both ends of the amorphous wire 2 are connected to the electrodes 8 each of which is formed of two layers of the electroless plating layer 4 and the electrolytic plating layer 5). For this reason, it is unnecessary to additionally form an electrode, and a producing process of the MI element 1 can be simplified.

According to the method for producing the MI element 101 of the present embodiment, the coil electrodes 106T and 106T can be formed in an annular shape that surrounds the insulator layer 3. For this reason, the coil electrodes 106T and 106T can oppose the substrate regardless of an attitude of the MI element 101, and thus, the coil electrodes 106T and 106T can be mounted on a substrate.

As described above, the method for producing the MI element according to an example of the present disclosure includes: the insulation step of forming the insulator layer on the outer periphery of the amorphous wire; the electroless plating step of forming the electroless plating layer on the outer peripheral surface of the insulator layer; the electrolytic plating step of forming the electrolytic plating layer on the outer peripheral surface of the electroless plating layer; the resist step of forming the resist layer on the outer peripheral surface of the electrolytic plating layer; the exposure step of exposing the resist layer with the laser to form the spiral groove strip on the outer peripheral surface of the resist layer; and the etching step of performing etching using the resist layer as the masking material and removing the electroless plating layer and the electrolytic plating layer in the groove strip to form the coil with the remaining electroless plating layer and electrolytic plating layer.

With this configuration, the performance of the MI element can be ensured by forming the metallic film to have a large thickness and ensuring the current path cross-sectional area of the current flowing through the electromagnetic coil.

Further, it is preferable that the method for producing the MI element include the coating step of coating the coil formed in the etching step with the resin layer and filling the resin between the coils.

With this configuration, the resin enters the gap between the coils so that it is possible to make it difficult for the coil to be separated.

Further, it is preferable that the thickness of the insulator layer be formed uniformly in the circumferential direction in the insulation step in the method for producing the MI element.

With this configuration, the sensitivity of the MI element can be improved.

Further, the method for producing the MI element is preferably configured such that: both ends of the amorphous wire are exposed from the insulator layer in the insulation step; the electroless plating layer is formed so as to come into contact with the both ends of the amorphous wire in the electroless plating step; the groove strip and a pair of annular grooves, which surround the resist layer to be separated from both ends of the groove strip on an outer end side, are formed in the exposure step; and in the etching step, the electroless plating layer and the electrolytic plating layer remaining on an outer end side of the pair of annular grooves are formed as electrodes of the amorphous wire, the electroless plating layer and the electrolytic plating layer remaining between the pair of annular grooves are formed as the coil, and both ends of the coil are formed as annular coil electrodes that surround the insulator layer.

With this configuration, the coil electrode can be formed in the annular shape that surrounds the insulator layer, and thus, the coil electrode can be mounted on the substrate regardless of the attitude of the MI element.

Further, the MI element according to an example of the present disclosure includes: an amorphous wire; an insulator layer formed on an outer periphery of the amorphous wire; and a coil formed in a spiral shape on an outer peripheral surface of the insulator layer, the coil being formed of two layers of an electroless plating layer and an electrolytic plating layer formed on an outer peripheral surface of the electroless plating layer.

With this configuration, the performance of the MI element can be ensured by forming the metallic film to have a large thickness and ensuring the current path cross-sectional area of the current flowing through the electromagnetic coil.

Further, the MI element is preferably configured such that the coil is covered with the resin layer and the gap between the coils is filled with the resin.

With this configuration, the resin enters the gap between the coils so that it is possible to make it difficult for the coil to be separated.

Further, it is preferable that the insulator layer have the uniform thickness in the circumferential direction in the MI element.

With this configuration, the sensitivity of the MI element can be improved.

Further, it is preferable that both ends of the amorphous wire be connected to the electrodes each of which is formed of two layers of the electroless plating layer that covers the end of the insulator layer and the electrolytic plating layer formed on the outer peripheral surface of the electroless plating layer in the MI element.

With this configuration, the electrode of the amorphous wire can be formed by the electroless plating layer and the electrolytic plating layer remaining on the outer end side of the annular groove, and thus, it is possible to simplify the producing process of the MI element.

Further, it is preferable that both ends of the coil be formed as the annular coil electrode that surrounds the insulator layer in the MI element.

With this configuration, the coil electrode can be formed in the annular shape that surrounds the insulator layer, and thus, the coil electrode can be mounted on the substrate regardless of the attitude of the MI element.

With the method for producing the MI element and the MI element according to the present disclosure, the performance of the MI element can be ensured by forming the metallic film to have a large thickness and ensuring the current path cross-sectional area of the current flowing through the electromagnetic coil.

This application is based on JP 2017-236346 A filed on Dec. 8, 2017, the contents of which are included in the present application. Note that the specific embodiments or example made in the section of the description of embodiments is merely given to clarify the technical contents of the present disclosure, and the present disclosure should not be construed in a narrow sense by limiting only to such specific examples.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A method for producing an MI element, comprising:
an insulation step of forming an insulator layer on an outer periphery of an amorphous wire;
an electroless plating step of forming an electroless plating layer on an outer peripheral surface of the insulator layer;
an electrolytic plating step of forming an electrolytic plating layer on an outer peripheral surface of the electroless plating layer;
a resist step of forming a resist layer on an outer peripheral surface of the electrolytic plating layer;
an exposure step of exposing the resist layer with a laser to form a spiral groove strip on an outer peripheral surface of the resist layer; and
an etching step of performing etching using the resist layer as a masking material and removing the electroless plating layer and the electrolytic plating layer in the groove strip to form a coil with the remaining electroless plating layer and electrolytic plating layer.

2. The method for producing the MI element according to claim 1, further comprising a coating step of coating the coil formed in the etching step with a resin layer and filling a gap between the coils with resin.

3. The method for producing the MI element according to claim 1, wherein a thickness of the insulator layer is formed uniformly in a circumferential direction in the insulation step.

4. The method for producing the MI element according to claim 1, wherein
both ends of the amorphous wire are exposed from the insulator layer in the insulation step,
the electroless plating layer is formed so as to come into contact with the both ends of the amorphous wire in the electroless plating step,
the groove strip and a pair of annular grooves, which surround the resist layer to be separated from both ends of the groove strip on an outer end side, are formed in the exposure step, and
in the etching step, the electroless plating layer and the electrolytic plating layer remaining on an outer end side of the pair of annular grooves are formed as electrodes of the amorphous wire, the electroless plating layer and the electrolytic plating layer remaining between the pair of annular grooves are formed as the coil, and both ends of the coil are formed as annular coil electrodes that surround the insulator layer.

5. An MI element comprising:
an amorphous wire;
an insulator layer formed on an outer periphery of the amorphous wire; and
a coil formed in a spiral shape on an outer peripheral surface of the insulator layer,
wherein the coil is formed of two layers of an electroless plating layer and an electrolytic plating layer formed on an outer peripheral surface of the electroless plating layer.

6. The MI element according to claim 5, wherein the coil is covered with a resin layer, and a gap between the coils is filled with resin.

7. The MI element according to claim 5 or 6, wherein a thickness of the insulator layer is formed uniformly in a circumferential direction.

8. The MI element according to claim 5, wherein both ends of the amorphous wire are connected to electrodes each of which is formed of two layers of an electroless plating layer that covers an end of the insulator layer and an electrolytic plating layer formed on an outer peripheral surface of the electroless plating layer.

9. The MI element according to claim 5, wherein both ends of the coil are formed as annular coil electrodes that surround the insulator layer.

10. The MI element according to claim 6, wherein a thickness of the insulator layer is formed uniformly in a circumferential direction.

11. The MI element according to claim 6, wherein both ends of the amorphous wire are connected to electrodes each of which is formed of two layers of an electroless plating layer that covers an end of the insulator layer and an electrolytic plating layer formed on an outer peripheral surface of the electroless plating layer.

12. The MI element according to claim 6, wherein both ends of the coil are formed as annular coil electrodes that surround the insulator layer.

13. An MI element comprising:
an amorphous wire;
an insulator layer formed on an outer periphery of the amorphous wire; and
a coil formed in a spiral shape on an outer peripheral surface of the insulator layer,
wherein the coil is formed of two layers of a first layer and a second layer formed on an outer peripheral surface of the first layer.

14. The MI element according to claim 13, wherein the coil is covered with a resin layer, and a gap between the coils is filled with resin.

15. The MI element according to claim 13, wherein a thickness of the insulator layer is formed uniformly in a circumferential direction.

16. The MI element according to claim 13, wherein both ends of the amorphous wire are connected to electrodes each of which is formed of two layers of a first layer that covers an end of the insulator layer and a second layer formed on an outer peripheral surface of the first layer.

17. The MI element according to claim 13, wherein both ends of the coil are formed as annular coil electrodes that surround the insulator layer.

18. The MI element according to claim 14, wherein a thickness of the insulator layer is formed uniformly in a circumferential direction.

19. The MI element according to claim 14, wherein both ends of the amorphous wire are connected to electrodes each of which is formed of two layers of a first layer that covers an end of the insulator layer and a second layer formed on an outer peripheral surface of the first layer.

20. The MI element according to claim 14, wherein both ends of the coil are formed as annular coil electrodes that surround the insulator layer.
